(19) United States
(12) Patent Application Publication
(10) Pub. No.: US 2025/0267922 A1
(43) Pub. Date: Aug. 21, 2025

(54) SEMICONDUCTOR STRUCTURE AND METHOD FOR FORMING THE SAME

(71) Applicant: TAIWAN SEMICONDUCTOR MANUFACTURING COMPANY LTD., HSINCHU (TW)

(72) Inventors: KUN-RONG HONG, TAICHUNG CITY (TW); WEN-LANG WU, TAICHUNG CITY (TW); YI-CHEN LI, TAICHUNG CITY (TW)

(21) Appl. No.: 18/582,702

(22) Filed: Feb. 21, 2024

(51) Int. Cl. H01L 21/8234; H01L 27/088; H01L 27/092; H01L 29/40; H01L 29/49; H01L 29/51

(52) U.S. Cl. CPC H10D 84/038; H10D 64/01; H10D 64/667; H10D 64/685; H10D 84/0142; H10D 84/83; H10D 84/85

(57) ABSTRACT

A semiconductor structure includes a first FET device and a second FET device. The first FET device includes a first metal gate, and the second FET device includes a second metal gate. The first metal gate includes a first high-k gate dielectric layer, a first oxygen-trapping layer over the first high-k gate dielectric layer, and a first metal nitride layer over the first oxygen-trapping layer. The second metal gate includes a second high-k gate dielectric layer, a second oxygen-trapping layer over the second high-k gate dielectric layer, and a second metal nitride layer over the second oxygen-trapping layer. The first metal nitride layer and the second metal nitride layer include a same material. A thickness of the first metal nitride layer is different from a thickness of the second metal nitride layer.

### BACKGROUND

The electronics industry has experienced ever-increasing demand for smaller and faster electronic devices that are able to simultaneously provide greater numbers of increasingly complex and sophisticated functions. Accordingly, there is a continuing trend in the semiconductor industry to manufacture low-cost, high-performance, and low-power integrated circuits (ICs). Such objectives been achieved in large part by scaling down semiconductor IC dimensions (e.g., minimum feature size), thereby improving production efficiency and reducing associated costs. However, such downscaling has introduced increased complexity to the semiconductor manufacturing process. Thus, the realization of continued advances in semiconductor ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart representing a method for forming a metal nitride layer in accordance with aspects of the present disclosure.

FIGS. 2A to 2C are schematic drawings showing various stages in a formation of a semiconductor structure in accordance with aspects of the present disclosure in one or more embodiments.

FIG. 3 is a flowchart representing a method for forming a semiconductor structure in accordance with aspects of the present disclosure.

FIGS. 4A to 4G are schematic drawings showing various stages in a formation of a semiconductor structure in accordance with aspects of the present disclosure in one or more embodiments.

FIGS. 5A to 5E are schematic drawings showing various stages in a formation of a semiconductor structure in accordance with aspects of the present disclosure in one or more embodiments.

FIG. 6 is a flowchart representing a method for forming a semiconductor structure in accordance with aspects of the present disclosure.

FIGS. 7A to 7H are schematic drawings showing various stages in a formation of a semiconductor structure in accordance with aspects of the present disclosure in one or more embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature on or over a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of brevity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Metal compound films or layers are widely used in semiconductor devices. For example, metal compound layers may be used as a diffusion barrier layer, an etch stop layer, a work function metal layer, and a gap-filling layer in a replacement-gate (RPG) approach. The metal compound layers may also be used as a diffusion barrier layer, an etch stop layer, and a metal routing layer in a back-end-of-line (BEOL) interconnect structure. It should be understood that the metal compound layer may be used in various applications, and not limited to the abovementioned schemes.

In accordance with the wide use of metal compound films mentioned above, control of both thickness and uniformity of the film during deposition has become increasingly important, particularly as the scale of the semiconductor devices becomes smaller and smaller.

The present disclosure therefore provides a method for forming a metal compound layer, such as a metal nitride layer, and a method for forming a semiconductor structure using the metal nitride layer. In some embodiments, a nitrogen-rich (N-rich) layer or an oxygen-rich (O-rich) layer is formed prior to the forming of the metal nitride layer. The N-rich layer and the O-rich layer facilitate formation of a metal nitride layer having greater thickness and improved uniformity. In some embodiments, the N-rich layer or the O-rich layer can be integrated into the RPG approach. In other embodiments, the N-rich layer or the O-rich layer can be integrated into a multiple-Vt device approach.

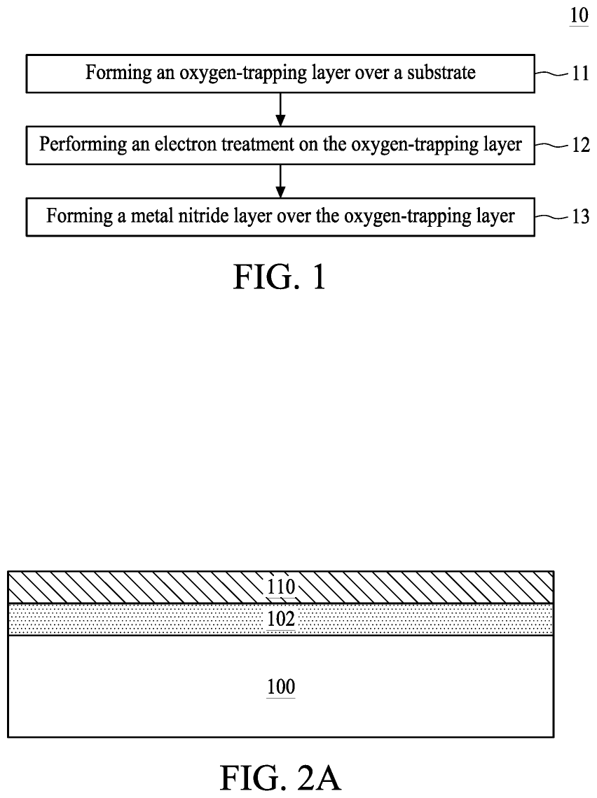

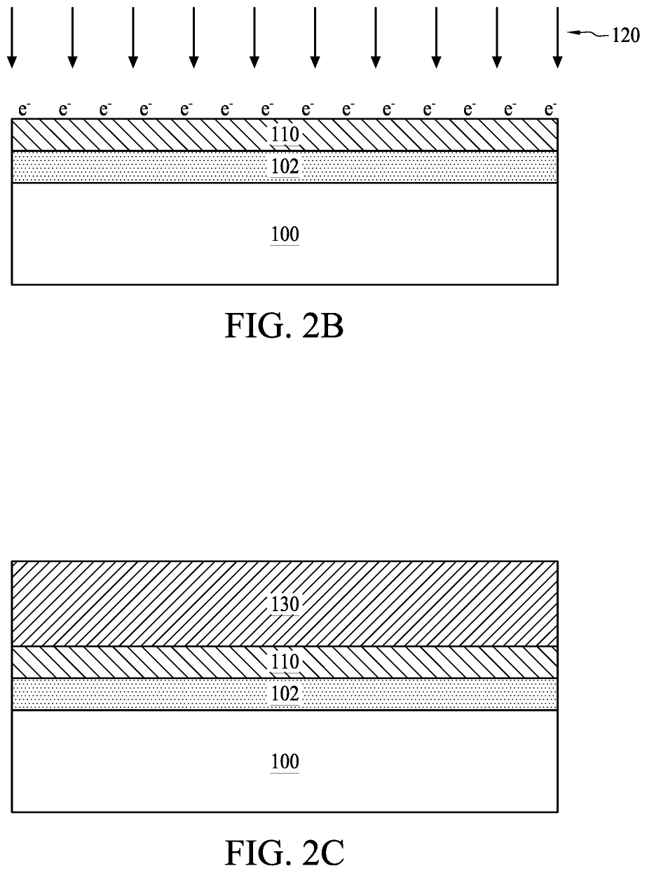

FIG. 1 is a flowchart representing a method for forming a metal nitride layer in accordance with aspects of the present disclosure, and FIGS. 2A to 2C are schematic drawings illustrating the method of forming the metal nitride layer at various fabrication stages in accordance with some embodiments of the present disclosure. In some embodiments, a method of forming a metal nitride layer 10 is provided. The method 10 includes a number of operations (11, 12 and 13).

Referring to FIGS. 1 and 2A, in some embodiments, a substrate 100 is received. In some embodiments, the substrate 100 may be a semiconductor substrate such as a silicon substrate. The substrate 100 may also include other semiconductors such as germanium (Ge), silicon carbide (SiC), silicon germanium (SiGe), or diamond. Alternatively, the substrate 100 may include a compound semiconductor and/or an alloy semiconductor. The substrate 100 may include various layers, including conductive or insulating layers formed on a semiconductor substrate.

In some embodiments, at least a conductive layer may be formed over the substrate 100. The conductive layer may include a single layer or, in some alternative embodiments, multiple layers. In some embodiments, the conductive layer may be a metal nitride layer 102 formed over the substrate 100, as shown in FIG. 2A. In some embodiments, the metal nitride layer 102 may be formed by film deposition, such as chemical vapor deposition (CVD), physical vapor deposition (PVD), atomic layer deposition (ALD), and/or other suitable processes. In some embodiments, the metal nitride layer 102 may be single layer including a titanium nitride (TiN) layer or a tantalum nitride (TaN) layer, but the disclosure is not limited thereto. In other embodiments, the metal nitride layer 102 may include multiple layers including a TiN layer and a TaN layer, but the disclosure is not limited thereto.

Still referring to FIG. 2A, in some embodiments, in operation 11, an oxygen-trapping layer 110 is formed over the substrate 100. Further, the oxygen-trapping layer 110 is formed on the metal nitride layer 102. In some embodiments, the oxygen-trapping layer 110 is defined to have an oxygen-trapping ability better than that of the underlying materials. In some embodiments, the oxygen-trapping layer 110 may be a silicon nitride layer. In such embodiments, a film deposition, such as CVD, PVD, ALD and/or other suitable processes, is performed on the metal nitride layer 102 to form the oxygen-trapping layer 110. Further, by adjusting parameters of the film deposition, a nitrogen concentration of the oxygen-trapping layer 110 (i.e., the silicon nitride layer) and a thickness of the oxygen-trapping layer 110 can be respectively modified in accordance with different process requirements. In some embodiments, the oxygen-trapping layer 110 including the silicon nitride layer may be referred to as an N-rich layer.

Sill referring to FIG. 2A, in some embodiments, the oxygen-trapping layer 110 may be a silicon oxide layer or a silicon oxide surface formed over a surface of the metal nitride layer 102. In some embodiments, the silicon oxide layer 110 may be formed over the metal nitride layer 102 by a film deposition, such as CVD, PVD, ALD and/or other suitable processes. In some embodiments, the silicon oxide surface may be formed by exposing the metal nitride layer 102 in an environment that includes oxygen. For example, the silicon oxide surface may be formed by exposing the metal nitride layer 102 to air, but the disclosure is not limited thereto. In some embodiments, an oxygen concentration of the oxygen-trapping layer 110 (i.e., the silicon oxide layer) and a thickness of the oxygen-trapping layer 110 may be respectively modified by adjusting parameters of the film deposition. In some embodiments, an oxygen concentration of the oxygen-trapping layer 110 (i.e., the silicon oxide surface) and a thickness of the oxygen-trapping layer 110 can be respectively modified by adjusting parameters of the environment. In some embodiments, the oxygen-trapping layer 110 including the silicon oxide layer or the silicon oxide surface can be referred to as an O-rich layer.

Referring to FIG. 2B, in some embodiments, in operation 12, an electron treatment 120 is performed on the oxygen-trapping layer 110. In some embodiments, a negative charged surface may be formed over the oxygen-trapping layer 110. Further, free-radical sites may be created by the electron treatment 120. The free-radical sites provide grafting possibilities in production of subsequently-formed materials and converted materials.

Referring to FIG. 2C, in some embodiments, in operation 13, a metal nitride layer 130 is formed over the oxygen-trapping layer 110. In some embodiments, the metal nitride layer 130 may be formed by film depositions, such as CVD, PVD, ALD and/or other suitable processes. In some embodiments, the metal nitride layer 130 may include TiN, TaN, titanium aluminum nitride (TiAlN), etc. It should be noted that the oxygen-trapping layer 110 helps to increase a thickness of the metal nitride layer 130. In some comparative approaches, when the metal nitride layer is formed over an underlying layer without the oxygen-trapping layer 110 and the negatively-charged surface, a deposition duration for forming the metal nitride layer is adjusted to achieve a target thickness. For example, a thicker metal nitride layer requires a greater deposition duration. In contrast with the comparative approaches, due to the oxygen-trapping layer 110, the deposition duration can be reduced while still forming a metal nitride layer 130 with the above-mentioned target thickness. In some embodiments, a deposition having a duration same as those of the comparative approaches (which lack the oxygen-trapping layer 110 and the negatively-charged surface) may provide an even thicker metal nitride layer 130. For example, with in a deposition having the same duration (compared to durations of the comparative approaches), the thickness of the metal nitride layer 130 formed over the oxygen-trapping layer 110 may be greater than approximately 1.5 times the thickness of a metal nitride layer formed without the oxygen-trapping layer 110. In other words, efficiency of the film deposition is improved due to the oxygen-trapping layer 110 (i.e., the N-rich layer or the O-rich layer) and the negatively-charged surface. In some embodiments, the film deposition is performed in a duration that is able to form the metal nitride layer 130 having a thickness of approximately 10 Å. However, due to the helps from the oxygen-trapping layer 320 and the negative surface, the final thickness of the metal nitride layer 130 may be greater than approximately 50 Å, but the disclosure is not limited thereto.

Accordingly, the method for forming the metal nitride layer 10 can be integrated into many fabrication applications. The method 10 provides the oxygen-trapping layer 110, which helps improve efficiency of film deposition.

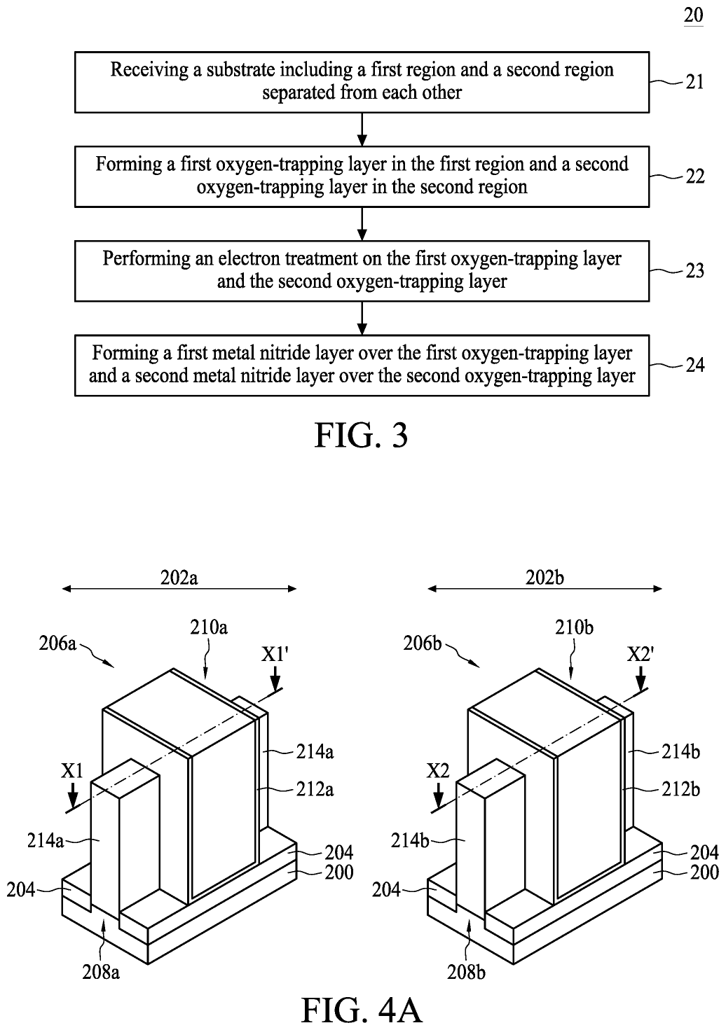

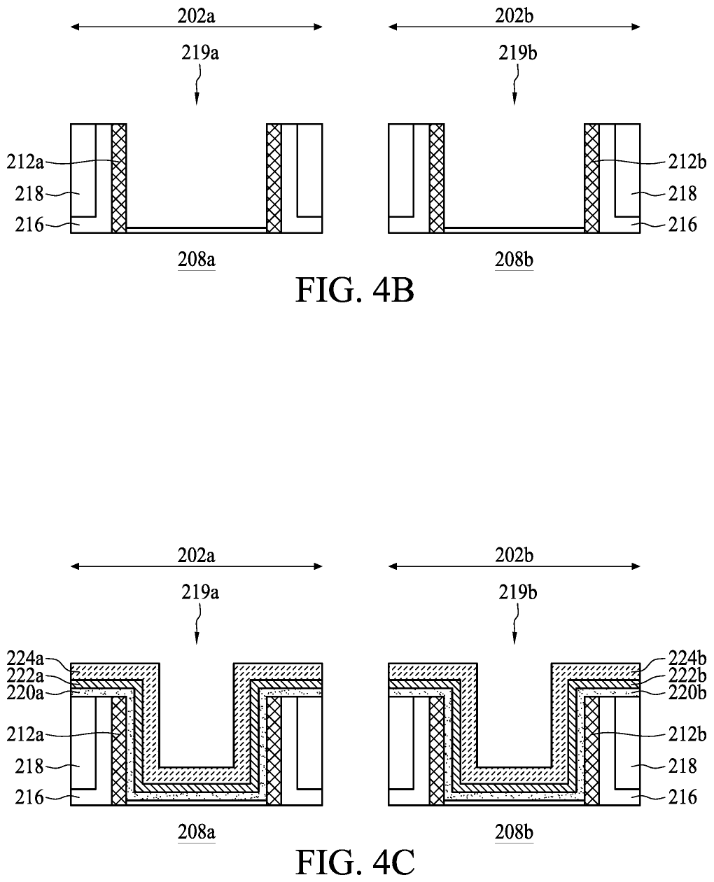

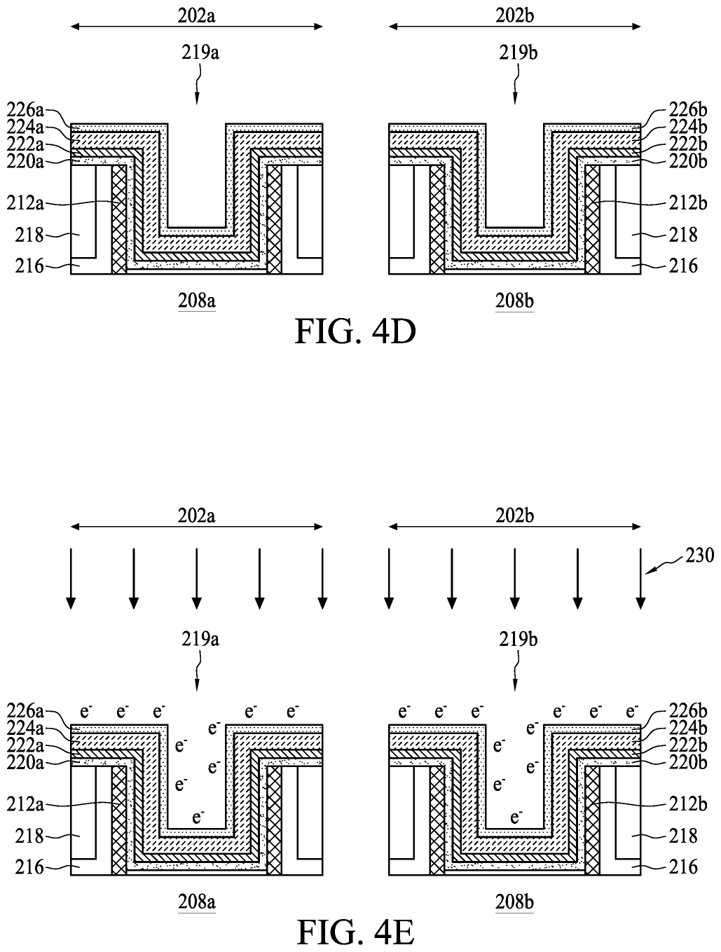

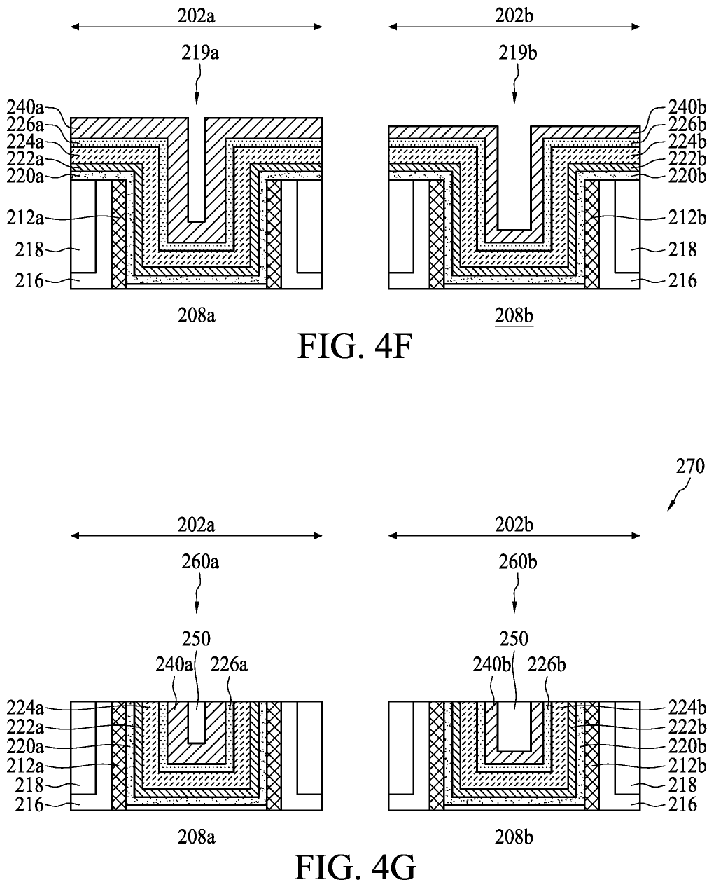

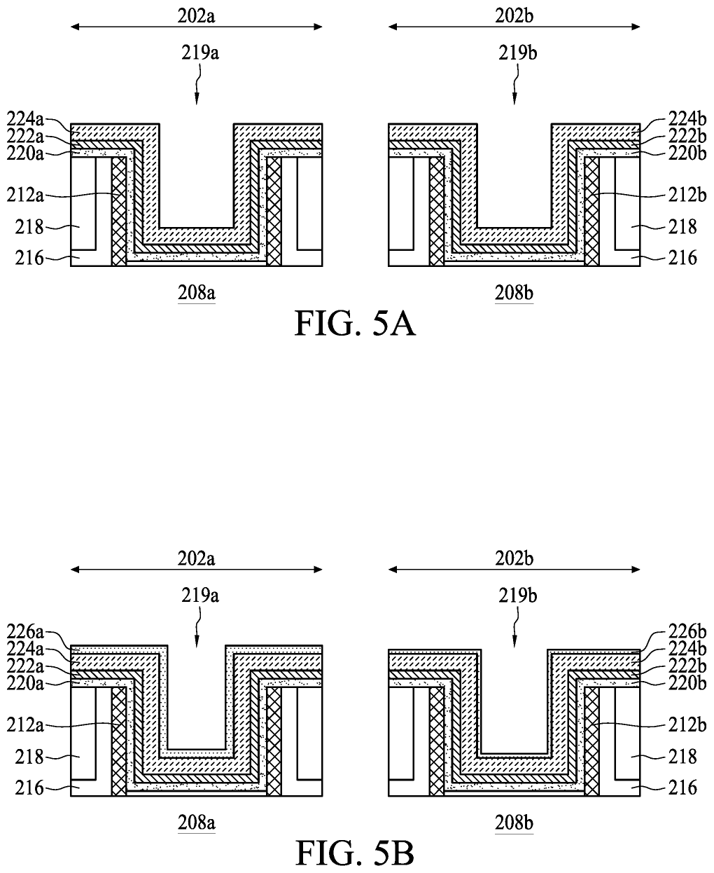

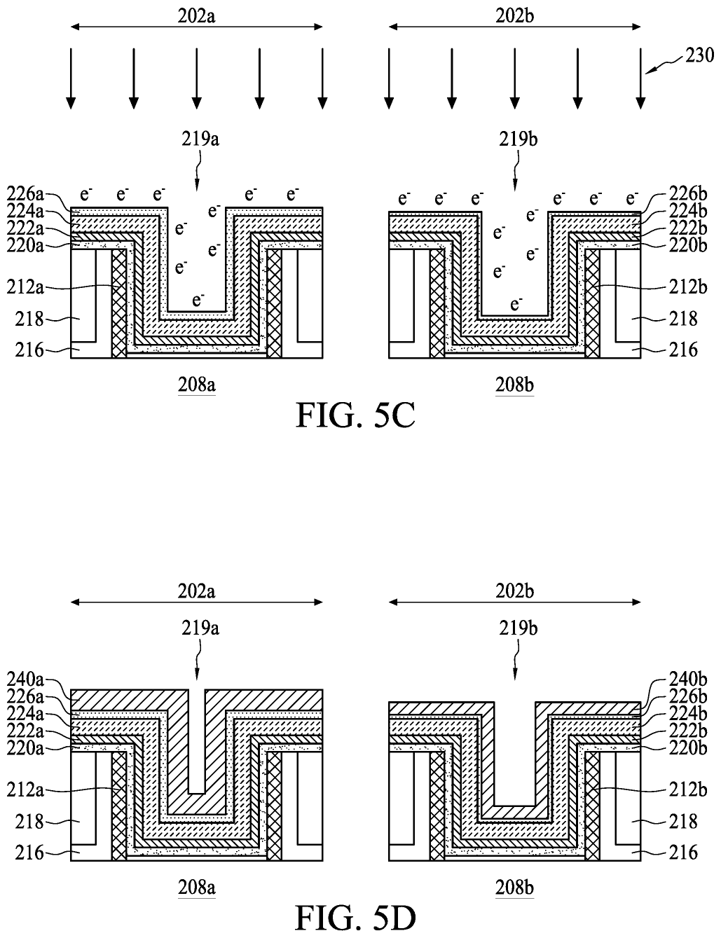

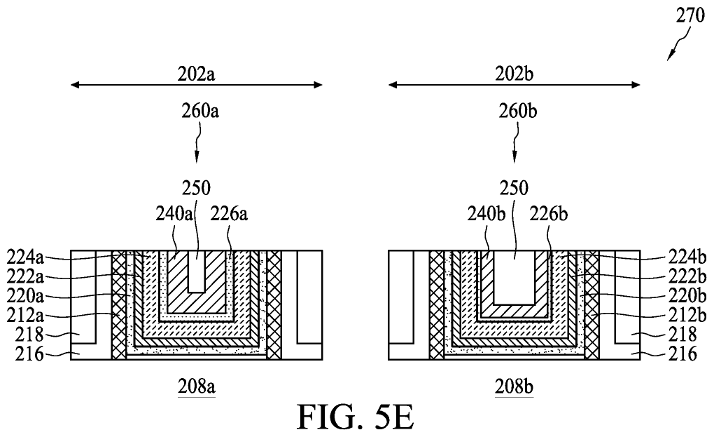

FIG. 3 is a flowchart representing a method for forming a semiconductor structure 20 in accordance with aspects of the present disclosure, and FIGS. 4A to 4G and FIGS. 5A to 5E are schematic drawings illustrating the method of forming the semiconductor structure at various fabrication stages in accordance with some embodiments of the present disclosure. In some embodiments, the method of forming the metal nitride layer 10 can be integrated into the method for forming the semiconductor structure 20. The method 20 includes a number of operations (21, 22, 23 and 24). Further, in some embodiments, the method for forming the semiconductor structure 20 can be integrated into various semiconductor manufacturing processes, such as an RPG scheme, but the disclosure is not limited thereto.

Referring to FIGS. 3 and 4A, in some embodiments, in operation 21, a substrate 200 is received. The substrate 200 may be a semiconductor substrate such as a silicon substrate. The substrate 200 may also include other semiconductors such as germanium (Ge), silicon carbide (SiC), silicon germanium (SiGe), or diamond. Alternatively, the substrate 200 may include a compound semiconductor and/or an alloy semiconductor. The substrate 200 may include various layers, including conductive or insulating layers formed on a semiconductor substrate. The substrate 200 may include various doping configurations depending on design requirements, as is known in the art. For example, different doping profiles (e.g., n wells or p wells) may be formed on the substrate 200 in regions designed for different device types (e.g., n-type field-effect transistors (NFET), or p-type field-effect transistors (PFET)). A suitable doping may include ion implantation of dopants and/or diffusion processes. As shown in FIG. 4A, the substrate 200 may have a first region 202a and a second region 202b defined thereon. Further, the substrate 200 may include isolation structures, e.g., shallow trench isolation (STI) structures 204 interposing the first region 202a and the second region 202b. In other words, the first region 202a and the second region 202b are separated from each other. The first region 202a and the second region 202b are defined for accommodating different devices.

Still referring to FIG. 4A, a first FET device 206a is formed in the first region 202a, and a second FET device 206b is formed in the second region 202b. In some embodiments, the first FET device 206a is a p-type FET device while the second FET device 206b is an n-type FET device, but the disclosure is not limited thereto. In some embodiments, the first FET device 206a includes a fin structure 208a, a sacrificial gate 210a, a spacer 212a and a source/drain 214a. The second FET device 206b includes a fin structure 208b, a sacrificial gate 210b, a spacer 212b and a source/drain 214b. A portion of the fin structure 208a covered by the sacrificial gate 210a serves as a channel region, and a portion of the fin structure 208b covered by the sacrificial gate 210b serves as a channel region. “Source/drain” may refer to a source or a drain, individually or collectively depending upon the context.

In some embodiments, each of the sacrificial gates 210a and 210b may include a dielectric layer and a sacrificial semiconductor layer. In some embodiments, the sacrificial semiconductor layers are made of polysilicon, but the disclosure is not limited thereto. In some embodiments, the spacers 212a and 212b can be formed over sidewalls of the sacrificial gates 210a and 210b. In some embodiments, the spacers 212a and 212b are made of silicon nitride (SiN), silicon carbide (SiC), silicon oxide (SiO), silicon oxynitride (SiON), or any other suitable material, but the disclosure is not limited thereto. In some embodiments, the spacers 212a and 212b are formed by deposition and etch-back operations.

As shown in FIG. 4A, in some embodiments, the source/drain 214a is formed over the fin structure 208a at two opposite sides of the sacrificial gate 210a. Similarly, the source/drain 214b is formed over the fin structure 208b at two opposite sides of the sacrificial gate 210b. In some embodiments, heights of the source/drain 214a and the source/drain 214b may be greater than heights of the fin structures 208a and 208b. In some embodiments, the source/drain 214a and the source/drain 214b may be formed by forming recesses in the fin structures 208a and 208b and growing a strained material in the recesses by an epitaxial (epi) process. In addition, a lattice constant of the strained material may be different from a lattice constant of the fin structures 208a and 208b. Accordingly, the source/drain 214a and the source/drain 214b may serve as stressors that improve carrier mobility. In some embodiments, the source/drain 214a and the source/drain 214b may both include n-type dopants, but the disclosure is not limited thereto.

Please refer to FIG. 4B, which shows cross-sectional views taken along lines X1-X1′ and X2-X2′ of FIG. 4A. In some embodiments, after the forming of the source/drain 214a and the source/drain 214b, a contact etch stop layer (CESL) 216 may be formed to cover the sacrificial gates 210a and 210b over the substrate 200. In some embodiments, the CESL 216 can include silicon nitride, silicon oxynitride, and/or other applicable materials. Subsequently, an inter-layer dielectric (ILD) structure 218 may be formed on the CESL 216 in accordance with some embodiments. The ILD structure 218 may include multilayers made of multiple dielectric materials, such as silicon oxide, silicon nitride, silicon oxynitride, tetraethoxysilane (TEOS), phosphosilicate glass (PSG), borophosphosilicate glass (BPSG), low-k dielectric material, and/or other applicable dielectric materials. Examples of low-k dielectric materials include, but are not limited to, fluorinated silica glass (FSG), carbon-doped silicon oxide, amorphous fluorinated carbon, parylene, bis-benzocyclobutenes (BCB), and polyimide. Next, a polishing process is performed on the ILD structure 218 and the CESL 216 to expose top surfaces of the sacrificial gates 210a and 210b. In some embodiments, the ILD structure 218 and the CESL 216 are planarized by a chemical mechanical polishing (CMP) process until the top surfaces of the sacrificial gates 210a and 210b are exposed.

In some embodiments, a gate trench 219a is formed in the first FET device 206a, and a gate trench 219b is formed in the second FET device 206b. In some embodiments, a width of the gate trench 219a is equal to a width of the gate trench 219b, but the disclosure is not limited thereto. In some embodiments, the sacrificial semiconductor layer is removed. In some embodiments, the dielectric layer may be removed for forming an interfacial layer (IL). In some embodiments, the dielectric layer may be left in the gate trench, though not shown. It should be noted that the removal of the dielectric layer may be performed depending on different process or product requirements.

Referring to FIG. 4C, in some embodiments, a high-k gate dielectric layer 220a is formed in the gate trench 219a, and a high-k gate dielectric layer 220b is formed in the gate trench 219b. A thickness of the high-k gate dielectric layer 220a and a thickness of the high-k dielectric layer 220b may be similar. In some embodiments, an IL layer may be formed prior to the forming of the high-k gate dielectric layers 220a and 220b, though not shown. The IL layer may include an oxide-containing material such as SiO or SiON. In some embodiments, the IL layer covers portions of the fin structures 208a and 208b exposed in the gate trenches 219a and 219b. The high-k gate dielectric layers 220a and 220b may be simultaneously formed on the IL layer and conformally formed in the gate trenches 219a and 219b. Accordingly, the high-k gate dielectric layer 220a covers at least sidewalls of the gate trench 219a, and the high-k gate dielectric layer 220b covers at least sidewalls of the gate trench 219b. In some embodiments, the high-k gate dielectric layers 220a and 220b include a high-k dielectric material having a high dielectric constant, for example, a dielectric constant greater than that of thermal silicon oxide (˜3.9). The high-k dielectric material may include hafnium oxide (HfO₂), zirconium oxide (ZrO₂), lanthanum oxide (La₂O₃), aluminum oxide (Al₂O₃), titanium oxide (TiO₂), yttrium oxide (Y₂O₃), strontium titanate (SrTiO₃), hafnium oxynitride (HfOₓN_{y}), other suitable metal-oxides, or combinations thereof.

Still referring to FIG. 4C, in some embodiments, layers such as diffusion barrier layers and etch stop layers may be formed in the gate trenches 219a and 219b, depending on various product and process requirements. For example, in some embodiments, a metal nitride layer 222a may be formed in the gate trench 219a, and a metal nitride layer 222b may be formed in the gate trench 219b. The metal nitride layer 222a may be formed over the high-k gate dielectric layer 220a, and the metal nitride layer 222b may be formed over the high-k gate dielectric layer 220b. The metal nitride layers 222a and 222b may include same materials and may be formed by a same film deposition. In some embodiments, the metal nitride layers 222a and 222b may include TiN, but the disclosure is not limited thereto. Further, a thickness of the metal nitride layer 222a is equal to a thickness of the metal nitride layer 222b.

Still referring to FIG. 4C, in some embodiments, a metal nitride layer 224a is formed in the gate trench 219a, and a metal nitride layer 224b is formed in the gate trench 219b. The metal nitride layer 224a may be formed over the metal nitride layer 222a, and the metal nitride layer 224b may be formed over the metal nitride layer 222b. The metal nitride layers 224a and 224b may include same materials and may be formed by a same film deposition. In some embodiments, the metal nitride layers 224a and 224b may include TaN, but the disclosure is not limited thereto. Further, a thickness of the metal nitride layer 224a is equal to a thickness of the metal nitride layer 224b.

Referring to FIGS. 3 and 4D, in some embodiments, in operation 22, an oxygen-trapping layer 226a is formed in the first region 202a and an oxygen-trapping layer 226b is formed in the second region 202b. As shown in FIG. 4D, the oxygen-trapping layer 226a is formed in the gate trench 219a, and the oxygen-trapping layer 226b is formed in the gate trench 219b. Further, the oxygen-trapping layer 226a may be formed over the metal nitride layer 224a, and the oxygen-trapping layer 226b may be formed over the metal nitride layer 224b. In some embodiments, each of the oxygen-trapping layer 226a and the oxygen-trapping layer 226b includes a silicon nitride layer, and the silicon nitride layers can be formed by the abovementioned film deposition. Although the oxygen-trapping layer 226a and the oxygen-trapping layer 226b both include silicon nitride, the oxygen-trapping layer 226a is different from the oxygen-trapping layer 226b. In some embodiments, the oxygen-trapping layer 226a and the oxygen-trapping layer 226b are formed by different film depositions. In some embodiments, by adjusting parameters of the film depositions, a nitrogen concentration of the oxygen-trapping layer 226a (i.e. the silicon nitride layer) is different from a nitrogen concentration of the oxygen-trapping layer 226b (i.e., the silicon nitride layer). For example, in some embodiments, the nitrogen concentration of the oxygen-trapping layer 226a may be greater than the nitrogen concentration of the oxygen-trapping layer 226b. As mentioned above, the oxygen-trapping layers 226a and 226b including the silicon nitride layers of different nitrogen concentrations may be referred to as N-rich layers.

In some embodiments, each of the oxygen-trapping layers 226a and 226b may include a silicon oxide layer formed by the abovementioned film depositions. Further, the oxygen-trapping layer 226a and the oxygen-trapping layer 226b may be formed by different film depositions. By adjusting parameters of the film depositions, an oxygen concentration of the oxygen-trapping layer 226a (i.e., the silicon oxide layer) is different from an oxygen concentration of the oxygen-trapping layer 226b (i.e., the silicon oxide layer). In other embodiments, both the oxygen-trapping layers 226a and 226b can be silicon oxide surfaces formed by exposing the metal nitride layers 224a and 224b in an environment that includes oxygen. Further, an oxygen concentration of the oxygen-trapping layer 226a (i.e., the silicon oxide surface) and an oxygen concentration of the oxygen-trapping layer 226b (i.e., the silicon oxide surface) can be respectively modified by adjusting parameters of the environment. In some embodiments, the oxygen concentration of the oxygen-trapping layer 226a is greater than the oxygen concentration of the oxygen-trapping layer 226b. As mentioned above, the oxygen-trapping layers 226a and 226b including the silicon oxide layers or the silicon oxide surfaces can be referred to as O-rich layers.

Referring to FIGS. 3 and 4E, in some embodiments, in operation 23, an electron treatment 230 is performed on the oxygen-trapping layers 226a and 226b. In some embodiments, a negatively-charged surface may be formed over the oxygen-trapping layers 226a and 226b, respectively. As mentioned above, free-radical sites that provide grafting possibilities in production of subsequently-formed materials and converted materials may be created by the electron treatment 230.

Referring to FIGS. 3 and 4F, in some embodiments, in operation 24, a metal nitride layer 240a is formed over the oxygen-trapping layer 226a in the gate trench 219a in the first region 202a, and a metal nitride layer 240b is formed over the oxygen-trapping layer 226b in the gate trench 219b in the second region 202b. The metal nitride layers 240a and 240b include a same material. In some embodiments, the metal nitride layers 240a and 240b may include TiN, TaN or TiAlN, but the disclosure is not limited thereto. In some embodiments, the metal nitride layers 240a and 240b may be formed by film depositions, such as CVD, PVD, ALD and/or other suitable processes. It should be noted that the oxygen-trapping layers 226a and 226b help to increase a thickness of the metal nitride layer 240a and a thickness of the metal nitride layer 240b. As mentioned above, due to the oxygen-trapping layers 226a and 226b and the negatively-charged surfaces, a deposition duration for forming the metal nitride layers 240a and 240b is reduced. In other words, efficiency of the film deposition is improved due to the oxygen-trapping layers 226a and 226b (i.e., the N-rich layers and the O-rich layers), and the negatively-charged surfaces. In some embodiments, the film deposition is performed in a duration that is able to form the metal nitride layers 240a and 240b having a thickness of approximately 10 Å. However, due to the helps from the oxygen-trapping layer 226a and 226b and the negative surface, the final thickness of the metal nitride layers 240a and 240b may be greater than approximately 50 Å, but the disclosure is not limited thereto. Further, because the thicknesses of the metal nitride layers 240a and 240b are increased by the oxygen-trapping layers 226a and 226b (i.e., the N-rich layers and the O-rich layers) and the negative charged surfaces, a gap-filling issue of the film deposition may be mitigated.

Still referring to FIG. 4F, in some embodiments, the metal nitride layer 240a and the metal nitride layer 240b are formed by a same film deposition. However, due to the different nitrogen concentrations or the different oxygen concentrations of the oxygen-trapping layers 226a and 226b, the thickness of the metal nitride layer 240a is different from the thickness of the metal nitride layer 240b. In some embodiments, the thicknesses of the metal nitride layers 240a and 240b are correlated with the nitrogen concentrations or the oxygen concentrations of the oxygen-trapping layers 226a and 226b. As mentioned above, in some embodiments, the nitrogen concentration or the oxygen concentration of the oxygen-trapping layer 226a is greater than the nitrogen concentration or the oxygen concentration of the oxygen-trapping layer 226b; therefore, the thickness of the metal nitride layer 240a is greater than the thickness of the metal nitride layer 240b. It should be noted that the metal nitride layers 240a and 240b including the different thicknesses are formed by one film deposition. In other words, without adjusting parameters of the film deposition, the metal nitride layers 240a and 240b spontaneously obtain the different thicknesses for different devices.

In some embodiments, the metal nitride layers 240a and 240b may be used as work function metal layers. In other embodiments, the metal nitride layers 240a and 240b may be used as other layers, such as diffusion barrier layers or etch stop layers. In such embodiments, various layers may be formed over the metal nitride layers 240a and 240b, though not shown.

Referring to FIG. 4G, in some embodiments, a gap-filling metal layer 250 is formed to fill the gate trenches 219a and 219b. The gap-filling metal layer 250 may include metal materials having low resistance, such as aluminum (Al), tungsten (W), copper (Cu), and/or other suitable materials, and may be formed by CVD, PVD, plating and/or other suitable processes. Further, a CMP is performed to remove superfluous materials. Accordingly, a metal gate 260a is obtained in the first region 202a, and a metal gate 260b is obtained in the second region 202b. In some embodiments, further processes, such as contact and via formation, interconnect processing, etc., may be performed subsequently to complete the fabrication of the metal gates 260a and 260b.

Please refer to FIGS. 5A to 5D, which are schematic drawings illustrating the method 20 of forming the semiconductor structure at various fabrication stages in accordance with some embodiments of the present disclosure. It should be noted that same elements in FIGS. 5A to 5D and FIGS. 4A to 4G may include same materials; therefore, repeated descriptions are omitted for brevity. Referring to FIG. 5A, in some embodiments, in operation 21, a substrate having a first region 202a and a second region 202b is received. Further, a first FET device is formed in the first region 202a, and a second FET device is formed in the second region 202b. Details of the substrate, the first FET device and the second FET device are similar to those described above; therefore, such details are omitted for brevity. As mentioned above, sacrificial gates of the first FET device 206a and the second FET device 206b are removed to form a gate trench 219a in the first region 202a and a gate trench 219b in the second region 202b. Further, as mentioned above, layers such as diffusion barrier layers and etch stop layers may be formed in the gate trenches 219a and 219b, depending on various product and process requirements. For example, in some embodiments, metal nitride layers 222a and 224a may be formed in the gate trench 219a, and metal nitride layers 222b and 224b are formed in the gate trench 219b. Details of the metal nitride layers 222a, 222b, 224a and 224b are similar to those described above; therefore, repeated descriptions of such details is omitted for brevity.

Referring to FIGS. 3 and 5B, in some embodiments, in operation 22, an oxygen-trapping layer 226a is formed in the first region 202a, and an oxygen-trapping layer 226b is formed in the second region 202b. As shown in FIG. 5B, the oxygen-trapping layer 226a is formed in the gate trench 219a, and the oxygen-trapping layer 226b is formed in the gate trench 219b. Further, the oxygen-trapping layer 226a may be formed over the metal nitride layer 224a, and the oxygen-trapping layer 226b may be formed over the metal nitride layer 224b. The oxygen-trapping layer 226a and the oxygen-trapping layer include a same material. In some embodiments, each of the oxygen-trapping layers 226a and 226b includes a silicon nitride layer. In some embodiments, each of the oxygen-trapping layers 226a and 226b includes a silicon oxide layer. In other embodiments, each of the oxygen-trapping layers 226a and 226b includes a silicon oxide surface. Although both the oxygen-trapping layers 226a and 226b include a same material, the oxygen-trapping layer 226a is different from the oxygen-trapping layer 226b. In some embodiments, the oxygen-trapping layer 226a and the oxygen-trapping layer 226b are formed by different film depositions. In some embodiments, by adjusting parameters of the film depositions, a thickness of the oxygen-trapping layer 226a is different from a thickness of the oxygen-trapping layer 226b, as shown in FIG. 5B. For example, in some embodiments, the thickness of the oxygen-trapping layer 226a may be greater than the thickness of the oxygen-trapping layer 226b.

Referring to FIGS. 3 and 5C, in some embodiments, in operation 23, an electron treatment 230 is performed on the oxygen-trapping layers 226a and 226b. In some embodiments, a negatively-charged surface may be formed over each of the oxygen-trapping layers 226a and 226b. As mentioned above, free-radical sites that provide grafting possibilities in production of subsequently-formed materials and converted materials may be created by the electron treatment 230.

Referring to FIGS. 3 and 5D, in some embodiments, in operation 24, a metal nitride layer 240a is formed over the oxygen-trapping layer 226a in the gate trench 219a in the first region 202a, and a metal nitride layer 240b is formed over the oxygen-trapping layer 226b in the gate trench 219b in the second region 202b. The metal nitride layers 240a and 240b include a same material. In some embodiments, the metal nitride layers 240a and 240b may include TiN, TaN or TiAlN, but the disclosure is not limited thereto. In some embodiments, the metal nitride layers 240a and 240b may be formed by film depositions, such as CVD, PVD, ALD and/or other suitable processes. It should be noted that the oxygen-trapping layers 226 and 226b help to increase a thickness of the metal nitride layer 240a and a thickness of the metal nitride layer 240b. As mentioned above, due to the oxygen-trapping layers 226a and 226b and the negatively-charged surfaces, a deposition duration for forming the metal nitride layers 240a and 240b is reduced. In other words, efficiency of the film deposition is improved due to the oxygen-trapping layers 226a and 226b (i.e., the N-rich layers and the O-rich layers), and the negatively-charged surfaces. In some embodiments, the film deposition is performed in a duration that is able to form the metal nitride layers 240a and 240b having a thickness of approximately 10 Å. However, due to the helps from the oxygen-trapping layers 226a and 226b and the negatively-charged surface, the final thickness of the metal nitride layers 240s and 240b may be greater than approximately 50 Å, but the disclosure is not limited thereto. Further, because the thicknesses of the metal nitride layers 240a and 240b are increased by the oxygen-trapping layers 226a and 226b (i.e., the N-rich layers and the O-rich layers) and the negatively-charged surfaces, a gap-filling issue of the film deposition may be mitigated.

Still referring to FIG. 5D, in some embodiments, the metal nitride layer 240a and the metal nitride layer 240b are formed by a same film deposition. However, due to the different thicknesses of the oxygen-trapping layers 226a and 226b, the thickness of the metal nitride layer 240a is different from the thickness of the metal nitride layer 240b. In some embodiments, the thicknesses of the metal nitride layers 240a and 240b are correlated with the thicknesses of the oxygen-trapping layers 226a and 226b. As mentioned above, in some embodiments, the thickness of the oxygen-trapping layer 226a is greater than the thickness of the oxygen-trapping layer 226b; therefore, the thickness of the metal nitride layer 240a is greater than the thickness of the metal nitride layer 240b. It should be noted that the metal nitride layers 240a and 240b including the different thicknesses are formed by one film deposition. In other words, without adjusting parameters of the film deposition, the metal nitride layers 240a and 240b spontaneously obtain different thicknesses for different devices.

As mentioned above, the metal nitride layers 240a and 240b may be used as a work function metal layer. In other embodiments, the metal nitride layers 240a and 240b may be used as other layers, such as diffusion barrier layers or etch stop layers. In such embodiments, various layers may be formed over the metal nitride layers 240a and 240b, though not shown. Referring to FIG. 5E, in some embodiments, a gap-filling metal layer 250 is formed to fill the gate trenches 219a and 219b. Further, a CMP is performed to remove superfluous materials. Accordingly, a metal gate 260a is obtained in the first region 202a, and a metal gate 260b is obtained in the second region 202b. In some embodiments, further processes, such as contact and via formation, interconnect processing, etc., may be performed subsequently to complete the fabrication of the metal gates 260a and 260b.

As mentioned above, the method for forming a metal nitride layer 10 can be integrated into many fabrication application. For example, the method 10 can be integrated in the method for forming the semiconductor structure 20. Further, the method 20 can be integrated into many fabrication applications, such as a CMOS device and an RPG scheme. The method 20 provides the metal nitride layers with spontaneously-obtained varying thicknesses and thus simplifies the fabrication process, and further improves the gap-filling result.

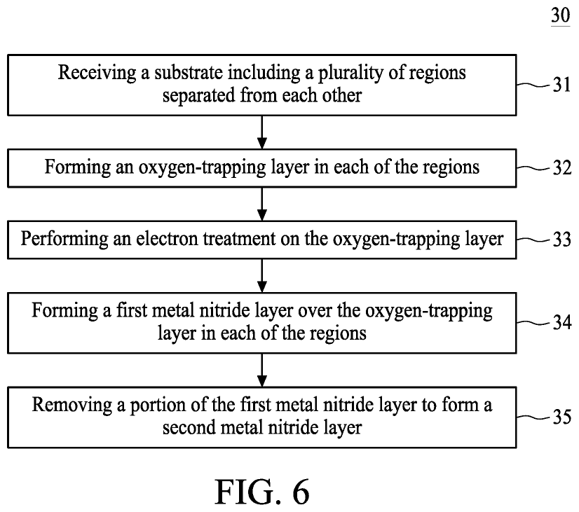

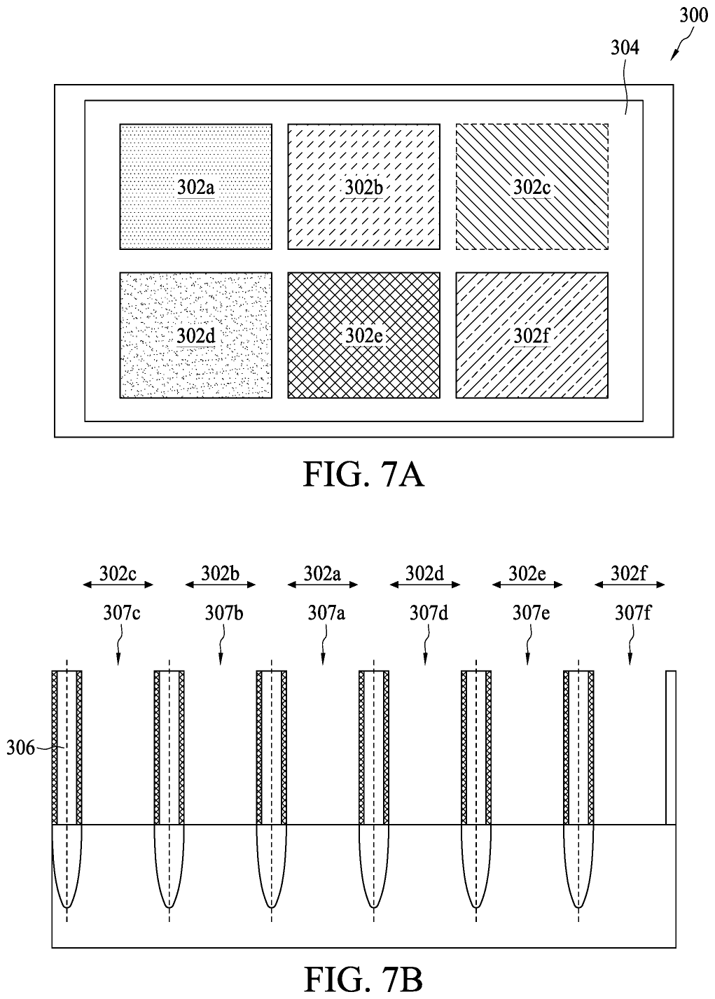

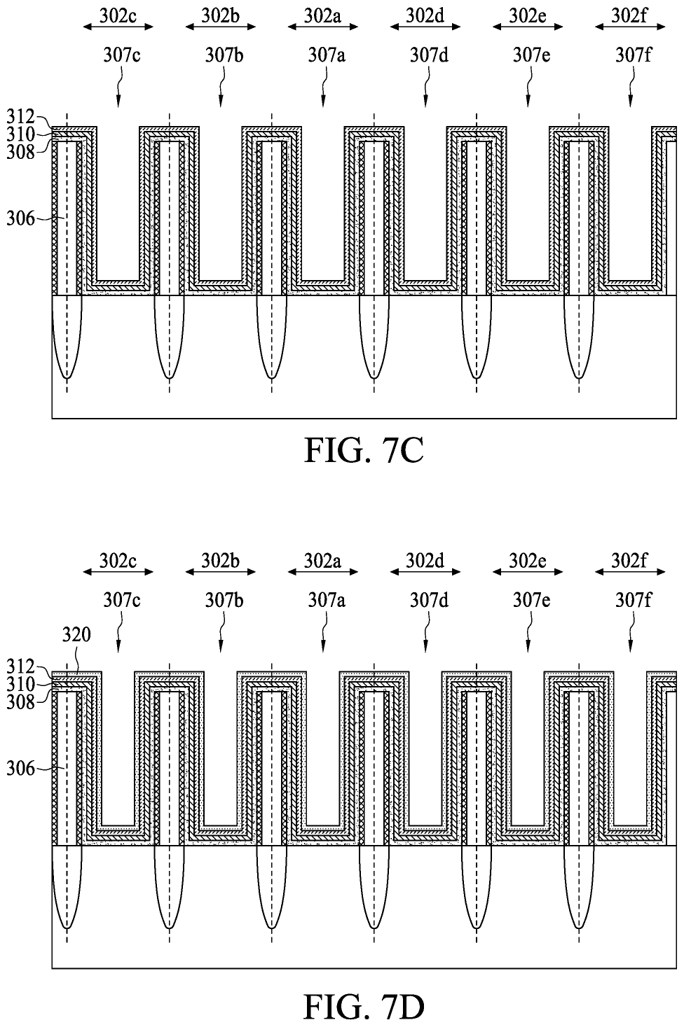

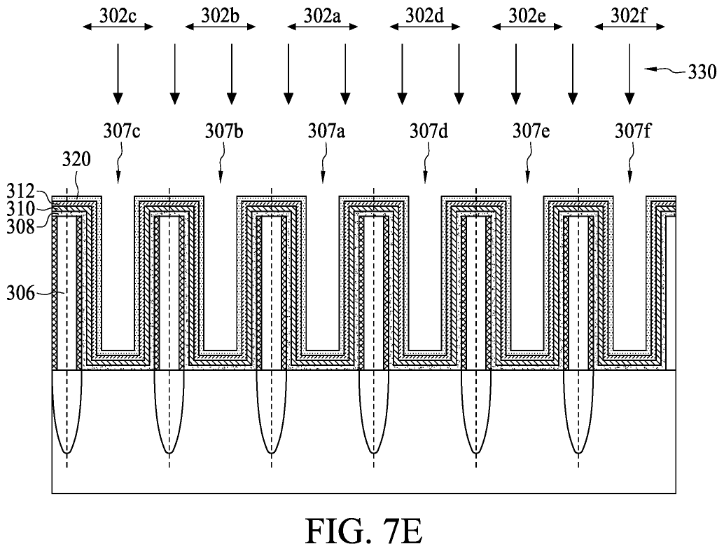

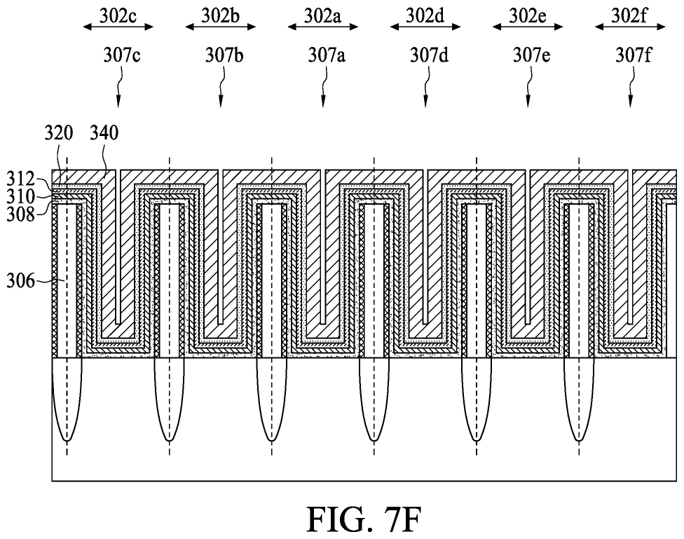

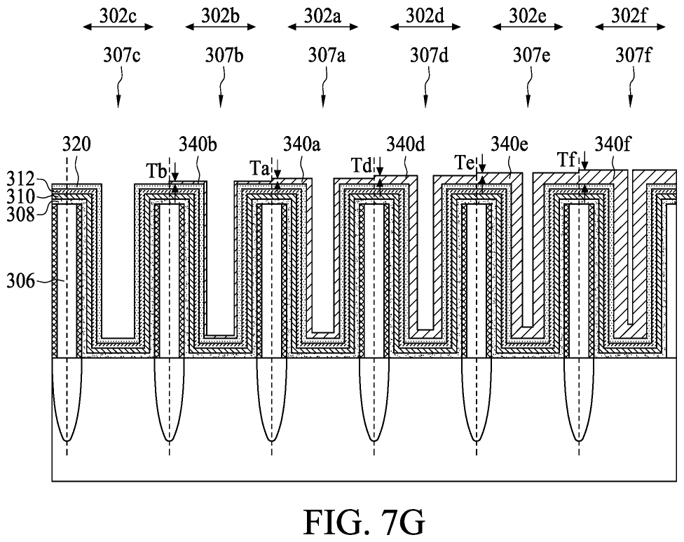

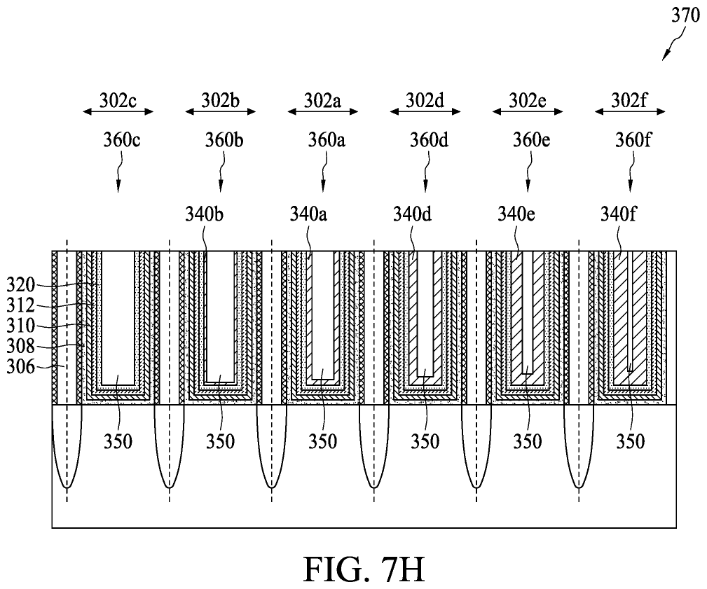

FIG. 6 is a flowchart of some embodiments of a method for forming a semiconductor structure 30, and FIGS. 7A to 7H are schematic drawings illustrating the method of forming the semiconductor structure 30 at various fabrication stages according to some embodiments of the present disclosure. In some embodiments, the method of forming the metal nitride layer 10 can be integrated into the method for forming the semiconductor structure 30. The method 30 includes a number of operations (31, 32, 33, 34 and 35). In some embodiments, the method for forming the semiconductor structure 30 can be integrated into many semiconductor manufacturing processes. For example, the method 30 can be integrated into an RPG scheme. Further, in some embodiments, the method for forming the semiconductor structure 30 can be integrated into a multi-Vt scheme, but the disclosure is not limited thereto.

Please refer to FIGS. 7A to 7H, which are schematic drawings illustrating the method of forming the semiconductor structure 30 at various fabrication stages in accordance with some embodiments of the present disclosure. It should be noted that same elements in FIGS. 7A to 7H and FIGS. 4A to 4G may include same materials; therefore, repeated descriptions are omitted for brevity. As shown in FIGS. 6 and 7A, in some embodiments, in operation 31, a substrate 300 is received. In some embodiments, the substrate 300 may include a plurality of regions 302a, 302b, 302c, 302d, 302e and 302f. In some embodiments, the regions 302a to 302f are defined to accommodate various devices. For example, the region 302a is defined to accommodate at least an n-type standard threshold voltage (NSVT) device, the region 302b is defined to accommodate at least an n-type low threshold voltage (NLVT) device, and the region 302c is defined to accommodate at least an n-type ultra-low threshold voltage (NuLVT) device. In some embodiments, the region 302d is defined to accommodate at least a p-type standard threshold voltage (PSVT) device, the region 302e is defined to accommodate at least a p-type low threshold voltage (PLVT) device, and the region 302f is defined to accommodate at least a p-type ultra-low threshold voltage (PuLVT) device. The regions 302a to 302f may work together to form a logic circuit, but the disclosure is not limited thereto. In some embodiments, other devices can be disposed in the regions 302a to 302f, depending on various application requirements. As shown in FIG. 7A, in some embodiments, the region 302a to 302f are separated from each other by isolation structures 304.

In some embodiments, a plurality of FET devices (not shown) are formed in the regions 302a to 302f. Each of the FET devices may include fin structures, a sacrificial gate, a spacer, and a source/drain, though not shown. In some embodiments, a dielectric structure 306 (shown in FIG. 7B) may be formed over the substrate 300 and surrounds the FET devices. The dielectric structure may include a CESL and an ILD structure, which may be similar to the CESL 216 and the ILD structure 218 described above; therefore, descriptions of such details are omitted for brevity.

Please refer to FIG. 7B, which is a cross-sectional view of the regions 302a to 302f. In some embodiments, the sacrificial gates of the FET devices are removed to form a gate trench 307a in the FET device in the region 302a, a gate trench 307b in the FET device in the region 302b, a gate trench 307c in the FET device in the region 302c, a gate trench 307d in the FET device in the region 302d, a gate trench 307e in the FET device in the region 302e, and a gate trench 307f in the FET device in the region 302f.

Referring to FIG. 7C, in some embodiments, a high-k gate dielectric layer 308 is formed in each of the gate trenches 307a to 307f. In some embodiments, an IL layer may be formed prior to the forming of the high-k gate dielectric layers 308, though not shown. As mentioned above, layers such as diffusion barrier layers and etch stop layers may be formed in the gate trenches 307a to 307f. For example, in some embodiments, a conductive layer 310 is formed in each of the gate trenches 307a to 307f. The conductive layer 310 may be formed over the high-k gate dielectric layer 308, as shown in FIG. 7C. In some embodiments, the conductive layer 310 may be a metal nitride layer. In some embodiments, the metal nitride layer may include TaN, but the disclosure is not limited thereto.

Still referring to FIG. 7C, as mentioned above, in some embodiments, another conductive layer 312 may be formed in each of the gate trenches 307a to 307f. The conductive layer 312 may be formed over the metal nitride layer 310. In some embodiments, the conductive layer 312 may include metal nitride or metal oxynitride. For example, the conductive layer 312 may include tantalum oxynitride (TaON), but the disclosure is not limited thereto.

Referring to FIGS. 6 and 7D, in some embodiments, in operation 32, an oxygen-trapping layer 320 is formed in each of the gate trenches 307a to 307f. Further, the oxygen-trapping layer 320 may be formed over the conductive layer 312. In some embodiments, the oxygen-trapping layer 320 includes a silicon nitride layer or a silicon oxide layer that can be formed by a film deposition similar to those mentioned above. In other embodiments, the oxygen-trapping layer 320 may be a silicon oxide surface. As mentioned above, a thickness of the oxygen-trapping layer 320 may be modified by adjusting parameters of the film deposition. Similarly, a nitrogen concentration or an oxygen concentration of the oxygen-trapping layer 320 may be modified by adjusting parameters of the film deposition. In some embodiments, the thickness of the oxygen-trapping layer 320 is less than a thickness of the each of the metal nitride layers 310 and 312. For example, by adjusting the parameters of the film deposition, the thickness of the oxygen-trapping layer 320 may be between approximately 5 angstroms (Å) and approximately 10 Å, but the disclosure is not limited thereto. As mentioned above, the oxygen-trapping layer 320 may be referred to as an N-rich layer or an O-rich layer.

Referring to FIGS. 6 and 7E, in some embodiments, in operation 33, an electron treatment 330 is performed on the oxygen-trapping layer 320. In some embodiments, a negatively-charged surface may be formed over the oxygen-trapping layer 320. As mentioned above, free-radical sites that provide grafting possibilities in production of subsequently-formed materials and converted materials may be created by the electron treatment 330.

Referring to FIGS. 6 and 7F, in some embodiments, in operation 34, a metal nitride layer 340 is formed over the oxygen-trapping layer 320 in each of the gate trenches 307a to 307f. In some embodiments, the metal nitride layer 340 may include TiN, TaN or TiAlN, but the disclosure is not limited thereto. In some embodiments, the metal nitride layer 340 may be formed by film depositions similar to those mentioned above. It should be noted that the oxygen-trapping layer 320 helps to increase a thickness of the metal nitride layer 340. As mentioned above, due to the oxygen-trapping layer 320 and the negatively-charged surface, a deposition duration for forming the metal nitride layer 340 is reduced. In other words, efficiency of the film deposition is improved due to the oxygen-trapping layer 320 (i.e., the N-rich layer and the O-rich layer) and the negatively-charged surface. In some embodiments, the film deposition is performed in a duration that is able to form the metal nitride layer 340 having a thickness of approximately 10 Å. However, due to the helps from the oxygen-trapping layer 320 and the negatively-surface, the thickness of the metal nitride layer 340 may be greater than approximately 50 Å, but the disclosure is not limited thereto. In some embodiments, because the thickness of the metal nitride layer 340 is increased by the oxygen-trapping layer 320 and the negative charged surface, a gap-filling issue of the film deposition may be mitigated.

In some embodiments, the metal nitride layer 340 may be used as a work function metal layer. It should be noted that different devices require different work functions. Further, an ability to adjust a work function by turning a material's thickness (i.e., as thickness increases, work function increases) is a well-known phenomenon. Therefore, by adjusting the thickness of the metal nitride layer 340, various work functions for various devices may be obtained. For example, in some embodiments, a portion of the metal nitride layer 340 is removed from the region 302a, such that the thickness of the metal nitride layer 340 is reduced to form a metal nitride layer 340a in the gate trench 307a in the region 302a, and the metal nitride layer 340a has a thickness Ta. In some embodiments, a portion of the metal nitride layer 340 is removed from the region 302b, such that the thickness of the metal nitride layer 340 is reduced to form a metal nitride layer 340b in the gate trench 307b in the region 302b, and the metal nitride layer 340b has a thickness Tb. In some embodiments, a portion of the metal nitride layer 340 is removed from the region 302d, such that the thickness of the metal nitride layer 340 is reduced to form a metal nitride layer 340d in the gate trench 307d in the region 302d, and the metal nitride layer 340d has a thickness Td. In some embodiments, a portion of the metal nitride layer 340 is removed from the region 302e, such that the thickness of the metal nitride layer 340 is reduced to form a metal nitride layer 340e in the gate trench 307e in the region 302e, and the metal nitride layer 340e has a thickness Te. In some embodiments, a portion of the metal nitride layer 340 may be entirely removed from the gate trench 307c in the region 302c. In some embodiments, the metal nitride layer having the thickness as originally deposited may be referred to a metal nitride layer 304f with the thickness Tf. As shown in FIG. 7G, the thickness Tf of the metal nitride layer 340f is greater than the thickness Te of the metal nitride layer 340e, the thickness Te of the metal nitride layer 340e is greater than the thickness Td of the metal nitride layer 340d, the thickness Td of the metal nitride layer 340d is greater than the thickness Ta of the metal nitride layer 340a, and the thickness Ta of the metal nitride layer 340a is greater than the thickness Tb of the metal nitride layer 340b. In some embodiments, due to various thicknesses, various work functions are obtained. In some embodiments, the thickness Tb of the metal nitride layer 340b, the thickness Ta of the metal nitride layer 340a, the thickness Td of the metal nitride layer 340d, the thickness Te of the metal nitride layer 340e, and the thickness Tf of the metal nitride layer 340f have a ratio, for example, Tb:Ta:Td:Te:Tf may be 1:1.9:3.8:4.9:5.4, but the disclosure is not limited thereto.

In some embodiments, the forming of the metal nitride layers 340a, 340b, 340d and 340e may be performed separately. In other embodiments, the forming of the metal nitride layers 340a, 340b, 340d and 340e may be sequentially performed. For example, in some embodiments, portions of the metal nitride layer 340 is removed from the regions 302c, 302b, 302a, 302d and 302e, while a portion of the metal nitride layer 340 in the region 302f is protected. Accordingly, the metal nitride layer 340e having the thickness Te is obtained in the gate trench 307e in the region 302e. In some embodiments, portion of the metal nitride layer 340 is subsequently removed from the regions 302c, 302b, 302a and 302d, while the metal nitride layers 340f and 340e in the regions 302f and 302e are protected. Accordingly, the metal nitride layer 340d having the thickness Td is obtained in the gate trench 307d in the region 302d. In some embodiments, portion of the metal nitride layer 340 is subsequently removed from the regions 302c, 302b and 302a, while the metal nitride layers 340f, 340e and 340d in the regions 302f, 302e and 302d are protected. Accordingly, the metal nitride layer 340a having the thickness Ta is obtained in the gate trench 307a in the region 302a. In some embodiments, portion of the metal nitride layer 340 is subsequently removed from the regions 302c and 302b, while the metal nitride layers 340f, 340e, 340d and 340a in the regions 302f, 302e, 302d and 302a are protected. Accordingly, the metal nitride layer 340b having the thickness Tb is obtained in the gate trench 307b in the region 302b. In some embodiments, the remained metal nitride layer 340 is subsequently removed from the region 302a, while the metal nitride layers 340f, 340e, 340d, 340a, and 340b in the regions 302f, 302e, 302d, 302a and 302b are protected. Accordingly, no metal nitride layer is left in the gate trench 307c in the region 302c.

In some embodiments, after the forming of the metal nitride layers 340a, 340b, 340d, 340e and 340f, various layers may be formed over the metal nitride layers 340a, 340b, 340d, 340e and 340f, though not shown.

Referring to FIG. 7H, in some embodiments, a gap-filling metal layer 350 is formed to fill the gate trenches 307a to 370f. Further, a CMP is performed to remove superfluous materials. Accordingly, a plurality of metal gate 360a to 360f are formed in the regions 302a to 302f, as shown in FIG. 7H. In some embodiments, further processes, such as contact and via formation, interconnect processing, etc., may be performed subsequently to complete the fabrication of the metal gates 360a to 360f.

As mentioned above, the method for forming a metal nitride layer 10 can be integrated into many fabrication applications. For example, the method 10 can be integrated into the method for forming the semiconductor structure 30. Further, the method 30 can be integrated into many semiconductor manufacturing applications, such as multi-Vt devices and an RPG scheme. Further, the method 30 provides the metal nitride layers having an improved gap-filling result.

Referring back to FIGS. 4G, 5E and 7H, in some embodiments, a semiconductor structure 270 is provided as shown in FIGS. 4G and 5E, and a semiconductor structure 370 is provided as shown in FIG. 7H. In some embodiments, the semiconductor structure 270 includes the first FET device 206a and the second FET device 206b. The first FET device 206a includes the metal gate 260a, and the second FET device 206b includes the metal gate 260b. The metal gates 260a, 260b include the high-k gate dielectric layers 220a, 220b, the oxygen-trapping layers 226a, 226b, the metal nitride layers 240a, 240b, and the gap-filling metal layer 250. The metal nitride layer 240a and the metal nitride layer 240b include a same material, but the thickness of the metal nitride layer 240a is different from the thickness of the metal nitride layer 240b. As mentioned above, the difference in thickness is a result of the different nitrogen concentrations or the different oxygen concentrations of the oxygen-trapping layers 226a and 226b. Alternatively, the difference in thickness is a result of the different thicknesses of the oxygen-trapping layers 226a and 226b. Accordingly, the first FET device 206a and the second FET device 206b having different doping types may obtain suitable work functions in accordance with the method 20.

Referring to FIG. 7H, in some embodiments, the semiconductor structure 370 includes FET devices including the metal gates 360a to 360f. The metal gates 360a to 360f include the high-k gate dielectric layer 308, the oxygen-trapping layers 320, the metal nitride layers 340a, 340b, 340d, 340e and 340f, and the gap-filling metal layer 350. The metal nitride layers 340a, 340b, 340d, 340e and 340f include a same material, but have differences in thicknesses. In some embodiments, the FET devices having same doping types may have metal nitride layers 340a and 340b of different thicknesses. The FET devices having same doping types may have metal nitride layers 340d, 340e and 340f of different thicknesses. In some embodiments, although the oxygen-trapping layers 320 in the metal gates 360a to 360d have a same thickness, the metal nitride layers 340a, 340b, 340d, 340e and 340f having different thicknesses can be obtained by the method for forming the semiconductor structure 30.

Accordingly, the present disclosure provides a method for forming a metal nitride layer and methods for forming a semiconductor structure using the method for forming the metal nitride layer. In some embodiments, an N-rich layer or an O-rich layer is formed prior to the forming of the target metal nitride layer. The N-rich layer and the O-rich layer facilitate formation of a metal nitride layer with greater thickness and an improved uniformity. In some embodiments, the N-rich layer or the O-rich layer can be integrated into an RPG approach. In further embodiments, the N-rich layer or the O-rich layer can be integrated into a multiple-Vt device approach.

In accordance with one embodiment of the present disclosure, a method of forming a metal nitride layer is provided. The method includes following operations. An oxygen-trapping layer is formed over a substrate. An electron treatment is performed on the oxygen-trapping layer. A first metal nitride layer is formed over the oxygen-trapping layer.

In accordance with one embodiment of the present disclosure, a method for forming a semiconductor structure is provided. The method includes following operations. A substrate is received. The substrate includes a first region and a second region separated from each other. A first oxygen-trapping layer is formed in the first region, and a second oxygen-trapping layer is formed in the second region. An electron treatment is performed on the first oxygen-trapping layer and the second oxygen-trapping layer. A first metal nitride layer is formed over the first oxygen-trapping layer, and a second metal nitride layer is formed over the second oxygen-trapping layer.

In accordance with one embodiment of the present disclosure, a semiconductor structure is provided. The semiconductor structure includes a first FET device and a second FET device. The first FET device includes a first metal gate, and the second FET device includes a second metal gate. The first metal gate includes a first high-k gate dielectric layer, a first oxygen-trapping layer over the first high-k gate dielectric layer, and a first metal nitride layer over the first oxygen-trapping layer. The second metal gate includes a second high-k gate dielectric layer, a second oxygen-trapping layer over the second high-k gate dielectric layer, and a second metal nitride layer over the second oxygen-trapping layer. The first metal nitride layer and the second metal nitride layer include a same material. A thickness of the first metal nitride layer is different from a thickness of the second metal nitride layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a metal nitride layer, comprising:
forming an oxygen-trapping layer over a substrate;
performing an electron treatment on the oxygen-trapping layer; and
forming a first metal nitride layer over the oxygen-trapping layer.

2. The method of claim 1, wherein the oxygen-trapping layer comprises a silicon nitride layer or a silicon oxide layer.

3. The method of claim 1, wherein the first metal nitride layer comprises a titanium nitride (TiN) layer or a tantalum nitride (TaN) layer.

4. The method of claim 1, further comprising forming a second metal nitride layer over the substrate, wherein the oxygen-trapping layer is formed over the second metal nitride layer.

5. The method of claim 4, wherein the second metal nitride layer comprises a TiN layer or a TaN layer.

6. A method for forming a semiconductor structure, comprising:
receiving a substrate comprising a first region and a second region separated from each other;
forming a first oxygen-trapping layer in the first region and a second oxygen-trapping layer in the second region;
performing an electron treatment on the first oxygen-trapping layer and the second oxygen-trapping layer; and
forming a first metal nitride layer over the first oxygen-trapping layer and a second metal nitride layer over the second oxygen-trapping layer,
wherein a thickness of the first metal nitride layer and a thickness of the second metal nitride layer are different from each other.

7. The method of claim 6, wherein the first oxygen-trapping layer comprises a first silicon nitride layer, and the second oxygen-trapping layer comprises a second silicon nitride layer.

8. The method of claim 7, wherein a nitrogen concentration of the first silicon nitride layer is different from a nitrogen concentration of the second silicon nitride layer.

9. The method of claim 7, wherein a thickness of the first silicon nitride layer is different from a thickness of the second silicon nitride layer.

10. The method of claim 6, wherein the first oxygen-trapping layer comprises a first silicon oxide layer, and the second oxygen-trapping layer comprises a second silicon oxide layer.

11. The method of claim 10, wherein an oxygen concentration of the first silicon oxide layer is different from an oxygen concentration of the second silicon oxide layer.

12. The method of claim 6, wherein the first metal nitride layer and the second metal nitride layer comprise a same material.

13. The method of claim 12, wherein the first metal nitride layer and the second metal nitride layer comprise a TiN layer or a TaN layer.

14. A semiconductor structure comprising:
a first field-effect transistor (FET) device comprising a first metal gate, wherein the first metal gate comprises:
a first high-k gate dielectric layer;
a first oxygen-trapping layer over the first high-k gate dielectric layer; and
a first metal nitride layer over the first oxygen-trapping layer; and
a second FET device comprising a second metal gate, wherein the second metal gate comprises:
a second high-k gate dielectric layer;
a second oxygen-trapping layer over the second high-k gate dielectric layer; and
a second metal nitride layer over the second oxygen-trapping layer,
wherein the first metal nitride layer and the second metal nitride layer comprise a same material, and a thickness of the first metal nitride layer is different from a thickness of the second metal nitride layer.

15. The semiconductor structure of claim 14, wherein the first FET device and the second FET device comprise a same doping type.

16. The semiconductor structure of claim 14, wherein the first FET comprises a first doping type and the second FET comprises a second doping type complementary to the first doping type.

17. The semiconductor structure of claim 14, wherein the first oxygen-trapping layer and the second oxygen-trapping layer comprise a same thickness.

18. The semiconductor structure of claim 14, wherein the first oxygen-trapping layer and the second oxygen-trapping layer comprises different thicknesses.

19. The semiconductor structure of claim 14, wherein each of the first oxygen-trapping layer and the second oxygen-trapping layer comprises a silicon nitride layer or a silicon oxide layer.

20. The semiconductor structure of claim 14, wherein the first metal nitride layer and the second metal nitride layer comprise a TiN layer or a TaN layer.
